(19) United States
(12) Patent Application Publication
(10) Pub. No.: US 2026/0128202 A1
(43) Pub. Date: May 7, 2026

(54) METHOD FOR MANUFACTURING MAGNETIC LAMINATED BODY AND MAGNETIC SENSOR, AND APPARATUS FOR MANUFACTURING MAGNETIC LAMINATED BODY

(71) Applicant: TDK Corporation, Tokyo (JP)

(72) Inventor: Hiroki OMURA, Tokyo (JP)

(73) Assignee: TDK Corporation, Tokyo (JP)

(21) Appl. No.: 19/366,811

(22) Filed: Oct. 23, 2025

(30) Foreign Application Priority Data
Nov. 1, 2024 (JP) 2024-192567

(51) Int. Cl. H01F 10/32; G01R 33/00; G01R 33/09; H10N 50/10; H10N 50/85

(52) U.S. Cl. CPC H01F 10/3272; G01R 33/0052; G01R 33/093; H01F 10/3286; H10N 50/10; H10N 50/85

(57) ABSTRACT

A laminated film comprising a ferromagnetic layer and an antiferromagnetic layer is formed in which the ferromagnetic layer and the antiferromagnetic layer are in contact with each other in a first direction. A magnetically pinned layer, which has a pinned magnetization direction with respect to an external magnetic field, is formed from the ferromagnetic layer by applying a magnetic field in the first direction to the laminated film. After stopping the application of the magnetic field, the magnetic laminated body is formed by heating the laminated film to a temperature equal to or higher than the blocking temperature of the antiferromagnetic layer.

### FIELD

This application claims the benefit of Japanese Priority Patent Application No. 2024-192567 filed on Nov. 1, 2024, the entire contents of which are incorporated herein by reference.

The present disclosure relates to a method for manufacturing a magnetic laminated body, a magnetic sensor, and an apparatus for manufacturing a magnetic laminated body.

### BACKGROUND

JP2018-6598A describes a magnetic sensor comprising a magnetically free layer whose magnetization direction changes with respect to an external magnetic field, a magnetically pinned layer whose magnetization direction is pinned with respect to the external magnetic field, and a nonmagnetic layer located between the magnetically free layer and the magnetically pinned layer. The magnetization direction of the magnetically pinned layer reverses when subjected to a strong magnetic field, and the magnetization direction may remain pinned in the reversed direction. To avoid this, a technique is known of providing an antiferromagnetic layer to strongly pin the magnetization direction of the magnetically pinned layer by exchange coupling between the antiferromagnetic layer and the magnetically pinned layer, as described in JP2015-207625A.

### SUMMARY

An object of the present disclosure is to provide a method for manufacturing a magnetic laminated body that allows simplification of a device for magnetizing a magnetically pinned layer and for heating an antiferromagnetic layer.

The method for manufacturing a magnetic laminated body of the present disclosure comprises the following steps: forming a laminated film comprising a ferromagnetic layer and an antiferromagnetic layer, wherein the ferromagnetic layer and the antiferromagnetic layer are in contact with each other in a first direction; applying a magnetic field in the first direction to the laminated film to form, from the ferromagnetic layer, a magnetically pinned layer whose magnetization direction is pinned with respect to an external magnetic field; and, after stopping the application of the magnetic field, heating the laminated film to a temperature equal to or higher than the blocking temperature of the antiferromagnetic layer.

The above and other objects, features, and advantages of the present application will become apparent from the following detailed description with reference to the accompanying drawings which illustrate the present application.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIGS. 1A and 1B are schematic drawings of a magnetic sensor according to a first example embodiment.

FIGS. 2A and 2B are schematic drawings showing a method of magnetizing a magnetically pinned layer and a method for heating a laminated film of the magnetic sensor shown in FIGS. 1A and 1B.

FIG. 3 is a schematic drawing of a device for applying a magnetic field to and heating the magnetic sensor shown in FIGS. 1A and 1B.

FIGS. 4A and 4B are schematic drawings of a magnetic sensor according to a second example embodiment.

FIG. 5 is a drawing of a structure of a laminated film in the second example embodiment.

FIG. 6 is a schematic drawing of a magnetic sensor according to a third example embodiment.

FIGS. 7A-7D are schematic drawings showing a method of magnetizing a magnetically pinned layer and a method for heating a laminated film of the magnetic sensor shown in FIG. 6.

FIG. 8 is a schematic drawing of a magnetic sensor according to a fourth example embodiment.

FIGS. 9A-9D are schematic drawings showing a method of magnetizing a magnetically pinned layer and a method for heating a laminated film of the magnetic sensor shown in FIG. 8.

FIGS. 10A and 10B are diagrams showing measurement results of magnetization curves in the examples and comparative examples.

### DETAILED DESCRIPTION

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

A magnetically pinned layer of a magnetic sensor must be magnetized, and, for the purpose of exchange coupling, an antiferromagnetic layer must be heated to a temperature equal to or higher than the blocking temperature. In the magnetic sensor described in JP2018-6598A, the magnetization direction of the magnetically pinned layer is oriented in the stacking direction of the magnetically free layer, the nonmagnetic layer, and the magnetically pinned layer. Therefore, magnetization of the magnetically pinned layer and heating of the antiferromagnetic layer must be performed from the same direction. However, since magnetization and heating are performed in the same process, a device for magnetization and heating is complicated.

Example embodiments of the present disclosure are described below with reference to the drawings. In the following description and drawings, the direction (first direction) in which the multiple layers of magnetic laminated body 6 and laminated film 601 are stacked is referred to as the Z-direction. The direction from magnetic laminated body 6 or the laminated film 601 to upper electrode layer 5 is referred to as the +Z-direction. The direction from magnetic laminated body 6 or laminated film 601 to lower electrode layer 7 or the substrate is referred to as the −Z-direction. The first direction means the +Z-direction or the −Z-direction. The direction orthogonal to the Z-direction is referred to as the X-direction. Although the X-direction is shown in the drawing for convenience, the X-direction may be any direction orthogonal to the Z-direction. Unless otherwise noted, white arrows in the drawings indicate the magnetization directions of first magnetically pinned layer 63 and second magnetically pinned layer 65. A bold line with an arrow indicates the magnetization direction of magnetically free layer 61 in a state in which an external magnetic field is not applied (hereinafter referred to as the zero magnetic field state).

### First Example Embodiment

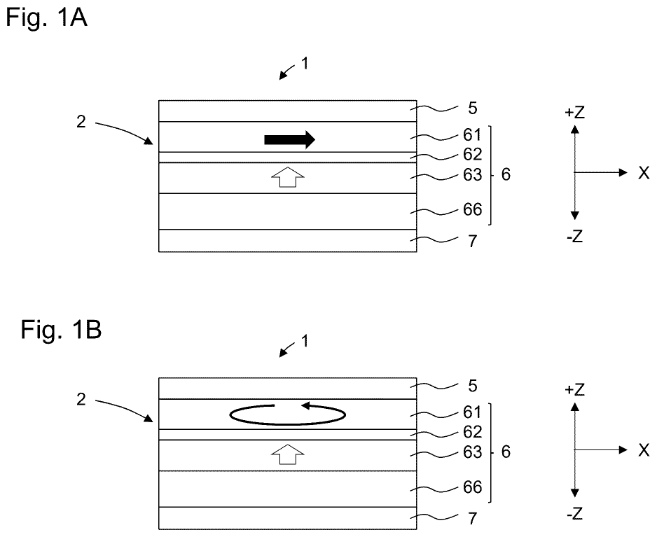

FIG. 1 a shows the schematic configuration of magnetic sensor 1 according to a first example embodiment. Magnetic sensor 1 may comprise magnetic field sensing element 2. Magnetic field sensing element 2 may comprise a silicon substrate (not shown), magnetic laminated body 6, and upper and lower electrode layers 5, 7 that supply a sense current to magnetic laminated body 6. Upper electrode layer 5, magnetic laminated body 6, and lower electrode layer 7 may be arranged on the substrate in the order of upper electrode layer 5, magnetic laminated body 6, and lower electrode layer 7 in the −Z-direction. Although not shown in the figure, there may be other layers between lower electrode layer 7 and the substrate, and lower electrode layer 7 may be separated from the substrate. Upper electrode layer 5 and lower electrode layer 7 may be formed by a multilayer film or the like that is made of conductors such as Ta, Cu, and Ru.

Magnetic laminated body 6 may comprise magnetically free layer 61, nonmagnetic layer 62, first magnetically pinned layer 63, and antiferromagnetic layer 66. These layers may be arranged in the order of magnetically free layer 61, nonmagnetic layer 62, first magnetically pinned layer 63 and antiferromagnetic layer 66 in the −Z-direction from upper electrode layer 5 to lower electrode layer 7. Layers adjacent to each other may be in contact with each other. In other words, first magnetically pinned layer 63 may be a magnetically pinned layer in contact with antiferromagnetic layer 66. These layers may also be stacked in the opposite direction. Specifically, the layers may be arranged in the order of antiferromagnetic layer 66, first magnetically pinned layer 63, nonmagnetic layer 62, and magnetically free layer 61 in the −Z-direction from upper electrode layer 5 to lower electrode layer 7.

Magnetically free layer 61 may be a magnetic layer whose magnetization direction changes with respect to an external magnetic field. Magnetically free layer 61 may be made of ferromagnetic materials such as Ni, Fe, Co, an alloy consisting of two or more of these, or an amorphous alloy made by adding B or Si to the alloy. The magnetization direction of magnetically free layer 61 may be oriented orthogonally to the Z-direction in the zero magnetic field state.

Nonmagnetic layer 62 may comprise an insulating layer such as MgO or Al₂O₃. Magnetic field sensing element 2 in this example embodiment may act as a tunnel magnetoresistive element (TMR element). Nonmagnetic layer 62 may comprise a nonmagnetic metal layer such as copper or silver. In this case, magnetic field sensing element 2 may act as a giant magnetoresistive element (GMR element). TMR elements may tend to provide higher output than GMR elements.

First magnetically pinned layer 63 may be a magnetic layer whose magnetization direction is pinned in the Z-direction. First magnetically pinned layer 63 may be formed from material having large perpendicular magnetic anisotropy, such as a multilayer film of Co, a multilayer film of Pd, or a multilayer of Co film and Ni film. First magnetically pinned layer 63 may be magnetized in the +Z-direction as in FIG. 1A but may also be magnetized in the −Z-direction.

Antiferromagnetic layer 66 may be formed from IrMn or from antiferromagnetic materials such as PtMn and FeRh. Antiferromagnetic layer 66 may stabilize the magnetization direction of first magnetically pinned layer 63 in the zero magnetic field state. Specifically, first magnetically pinned layer 63 may be exchange coupled with antiferromagnetic layer 66 and pinned in the same direction as the magnetization direction during magnetization and annealing. If a strong Z-direction magnetic field is applied in the direction opposite to the magnetization direction of first magnetically pinned layer 63, the magnetization direction of first magnetically pinned layer 63 may be temporarily reversed. If the magnetization direction of first magnetically pinned layer 63 remains reversed, the slope of the output may be inverted (e.g., a right-upward output curve may become a right-downward output curve). However, the magnetization direction of first magnetically pinned layer 63 may return to the original direction when the zero magnetic field state is attained. Therefore, the magnetization direction of first magnetically pinned layer 63 in the zero magnetic field state may be easily stabilized and the output may be less likely to reverse.

When an external magnetic field comprising a component in the Z-direction is applied to magnetically free layer 61, the magnetization direction of magnetically free layer 61 may tilt in the Z-direction. This tilting may change the angle between the magnetization direction of magnetically free layer 61 and the magnetization direction of first magnetically pinned layer 63, and the electrical resistance of magnetic laminated body 6 may change due to the magnetoresistance effect. The intensity of the Z-direction component of the external magnetic field may be measured by detecting the change in electrical resistance of magnetic laminated body 6, and in this way, magnetic sensor 1 of this example embodiment may detect the magnetic field in the Z-direction.

FIG. 1B shows the schematic structure of a variation of magnetic sensor 1 of the first example embodiment. The magnetization direction of magnetically free layer 61 may have a vortex shape in a plane perpendicular to the Z-direction in the zero magnetic field state. The magnetization state of magnetically free layer 61 in the zero magnetic field state may be determined by the balance between the exchange energy and the static magnetization energy of magnetically free layer 61. In general, vortex shapes may be more likely to occur when the saturation magnetization is large. In the zero magnetic field state, the center of the vortex, which is called a core, may be located at the center of magnetically free layer 61, and the magnetization direction may describe a concentric circle around the core. When an external magnetic field in the Z-direction is applied, the magnetization direction may be overall tilted in the Z-direction, resulting in a magnetoresistance effect similar to that in the first example embodiment. In this variation, because magnetically free layer 61 has a vortex shape in the zero magnetic field state, fluctuations in sensitivity when subjected to a magnetic field other than in the Z-direction may be easily suppressed.

### Method for Manufacturing Magnetic Sensor 1

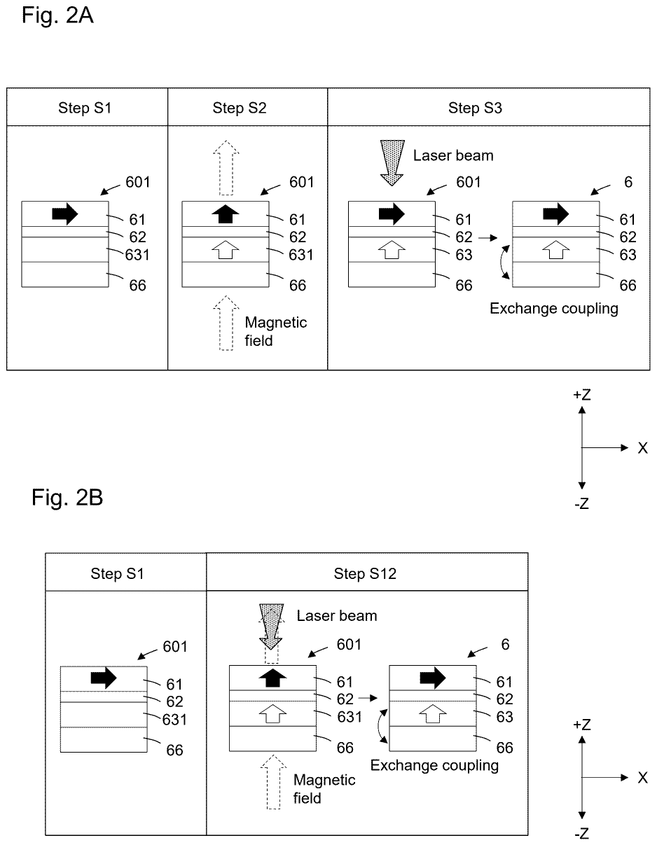

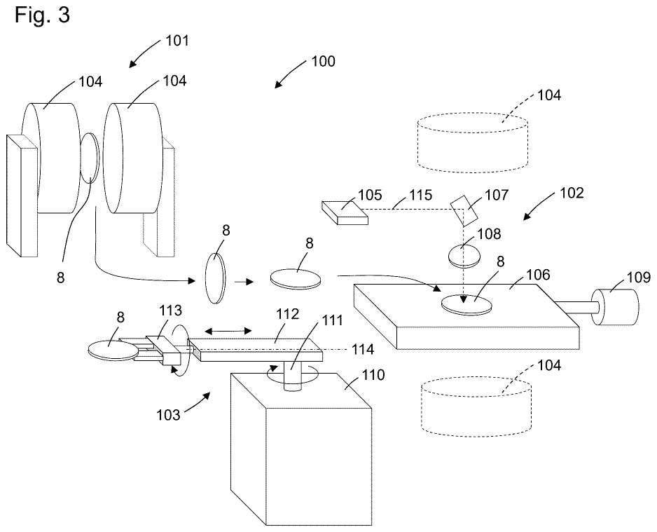

Next, a manufacturing method of magnetic sensor 1 of this example embodiment will be described with reference to FIGS. 2A-3. FIG. 2A is a schematic view showing a part of the manufacturing process of magnetic sensor 1 of this example embodiment, and FIG. 2B is a schematic view showing a part of the manufacturing process of the magnetic sensor of Comparative Example 1. In FIGS. 2A and 2B, dashed-line arrows indicate magnetic fields, and shaded arrows indicate local heating. Although FIGS. 2A and 2B show only one multilayer film 601, magnetic sensor 1 may be manufactured in units of wafers 8 in which a plurality of multilayer films 601 is formed. The magnetic sensors of this example embodiment and Comparative Example 1 may have the same structure, but the manufacturing processes may be different.

To manufacture magnetic sensor 1, lower electrode layer 7, laminated film 601, and upper electrode layer 5 may be first sequentially formed on wafer 8 (see FIG. 3) which is a substrate (Step S1). Laminated film 601 may be formed by sequentially forming antiferromagnetic layer 66, ferromagnetic layer 631, nonmagnetic layer 62, and magnetically free layer 61 in the +Z-direction on lower electrode layer 7. Ferromagnetic layer 631 will be magnetized to become first magnetically pinned layer 63, but at this stage, ferromagnetic layer 631 is not magnetized and is therefore distinguished from first magnetically pinned layer 63. Ferromagnetic layer 631 and antiferromagnetic layer 66 may be in contact with each other in the Z-direction. The above manufacturing process may be common to both this example embodiment and Comparative Example 1.

In this example embodiment, a magnetization process (Step S2) in which a magnetic field is applied to laminated film 601 to magnetize ferromagnetic layer 631, and a local heating process (Step S3), in which laminated film 601 is locally heated, may be performed next. Specifically, a magnetic field in the +Z-direction may be applied to laminated film 601 (or a magnetic field in the −Z-direction may be applied) to form, from ferromagnetic layer 631, first magnetically pinned layer 63, which has a magnetically pinned direction relative to the external magnetic field, following which the application of the magnetic field may be stopped (Step S2). Laminated film 601 may be then heated (annealed) at a temperature equal to or higher than the blocking temperature of antiferromagnetic layer 66 to form magnetic laminated body 6 (Step S3). The blocking temperature may be determined by the material of antiferromagnetic layer 66. By heating antiferromagnetic layer 66 to a temperature equal to or higher than the blocking temperature of antiferromagnetic layer 66, exchange coupling may occur between antiferromagnetic layer 66 and first magnetically pinned layer 63. The magnetization process (Step S2) and the local heating process (Step S3) may not be performed simultaneously or at overlapping times, but rather, may be performed at completely separate times. The magnetization direction of magnetically free layer 61 is temporarily tilted in the Z-direction in Step S2, but since no magnetic field is applied in Step S3, the magnetization direction switches to the X-direction, which is the direction of easy magnetization.

FIG. 3 shows the schematic structure of magnetizing and heating device 100 used in this example embodiment. Magnetizing and heating device 100 may be a part of the apparatus for manufacturing magnetic laminated body 6. Magnetizing and heating device 100 may comprise magnetic field application device 101, heating device 102 and transfer device 103. Magnetic field application device 101 may apply a magnetic field in the Z-direction to laminated film 601 (ferromagnetic layer 631) to form, from ferromagnetic layer 631, first magnetically pinned layer 63, which has a pinned magnetization direction with respect to the external magnetic field. Magnetic field application device 101 may comprise a pair of magnets 104 for applying a magnetic field to wafer 8, and a holding device for wafer 8 (not shown). The pair of magnets 104 may comprise electromagnets or permanent magnets. In FIG. 3, wafer 8 is held vertically between the pair of magnets 104, but the orientations of the pair of magnets 104 and wafer 8 are not limited to the example shown in the drawing. For example, the pair of magnets 104 may be arranged at an upper position and a lower position and wafer 8 may be held horizontally between the pair of magnets 104.

Heating device 102 may heat laminated film 601 to a temperature equal to or higher than the blocking temperature of antiferromagnetic layer 66. Heating device 102 may be capable of local heating of laminated film 601. For example, heating device 102 may comprise laser beam irradiation device 105 for heating laminated film 601 with a laser beam. Heating device 102 may comprise stage 106 that holds wafer 8 horizontally, laser beam irradiation device 105, reflecting mirror 107 for converting the optical path of the laser beam, and objective lens 108. Stage 106 may be driven in two mutually orthogonal directions parallel to the wafer holding surface of stage 106 by a linear guide (not shown) driven by motor 109.

Transfer device 103 may transfer wafer 8 (laminated film 601) between magnetic field application device 101 and heating device 102. Transfer device 103 may comprise base 110, rotation axis 111 supported by base 110, arm 112 connected to rotation axis 111 at an approximate right angle, and wafer holding section 113 connected to arm 112. Arm 112 may be rotatable around rotation axis 111 and extendable and retractable in the direction of long axis 114 of arm 112 itself. Wafer holding section 113 may be rotatable around long axis 114 of arm 112. This rotation may allow transfer device 103 to remove vertically oriented wafer 8 from magnetic field application device 101, to change the orientation of wafer 8, and to place wafer 8 horizontally on stage 106 of heating device 102. The structure of transfer device 103 is not limited to this configuration, and transfer device 103 may for example be used in combination with a conveyor for transporting wafer 8.

In Comparative Example 1 shown in FIG. 2B, magnetic laminated body 601 may be formed by heating (annealing) laminated body 601 at a temperature equal to or higher than the blocking temperature of antiferromagnetic layer 66 while applying a magnetic field in the +Z-direction to laminated body 601 (Step S12). First magnetically pinned layer 63 having a pinned magnetization direction relative to the external magnetic field may be formed, and at the same time, exchange coupling may occur between antiferromagnetic layer 66 and first magnetically pinned layer 63. The number of steps in Comparative Example 1 may be fewer than in this example embodiment, and the required time in Comparative Example 1 may also be shorter than in this example embodiment. However, in Comparative Example 1, one of magnets 104 may tend to interfere with laser beam irradiation optical path 115 because the direction of the applied magnetic field and the direction of heating (laser beam irradiation direction) may be oriented in the same direction (the Z-direction). Specifically, Step S12 of Comparative Example 1 may be performed if the pair of magnets 104 are placed in the positions shown by dashed lines in FIG. 3, but one magnet 104 may need to be placed farther from stage 106 than elements of the optical system such as reflecting mirror 107 and objective lens 108, and the distance between the two magnets 104 will increase. Applying a magnetic field of at least several thousand Oe (several hundred thousand A/m) may be for magnetizing ferromagnetic layer 631, but the increase in the distance between the two magnets 104 may entail an increase in the size of magnets 104, and in the case of electromagnets, the increased size of components such as coils and the like will increase both the size and the power consumption.

In Comparative Example 1, motor 109 for position control of stage 106 may likely be subjected to a relatively strong magnetic field. Since iron (ferromagnetic material) is typically used in motors on the market, a strong magnetic field may generate an attractive force on the motor, and this force may adversely affect the positional accuracy of laser beam irradiation. A motor that does not use iron is impractical. Arranging a magnet with a hole between reflecting mirror 107 or objective lens 108 and stage 106 and then using the hole in the magnet as an optical path for the laser beam can be considered, but motor 109 will still be similarly subjected to the magnetic field.

As previously described, the magnetizing process and the local heating process are performed at different times in this example embodiment, and magnetic field application device 101 for the magnetizing process and heating device 102 for the local heating process may therefore be installed as separate devices. In this case, since interference between laser beam irradiation optical path 115 and magnet 104 may not occur in principle, and further, interference between magnetic field application device 101 and heating device 102 may also be unlikely to occur, the respective structures of magnetic field application device 101 and heating device 102 are simplified. Furthermore, because magnetic field application device 101 and heating device 102 may be located far apart from each other, the influence of the magnetic field from magnetic field application device 101 is unlikely to affect heating device 102.

Because ferromagnetic layer 631 may be magnetized in the Z-direction in this example embodiment, the magnetization process (Step S2) and the local heating process (Step S3) can easily be performed separately. When a magnetic field in the Z-direction is applied to ferromagnetic layer 631, ferromagnetic layer 631 is magnetized in the Z-direction and remains magnetized in the Z-direction even when the application of the magnetic field is stopped. This characteristic arises because ferromagnetic layer 631 has large magnetic anisotropy in the film thickness direction (the Z-direction), whereby magnetization in the Z-direction is stable and not prone to fluctuation. First magnetically pinned layer 63 magnetized in the Z-direction is consequently obtained by performing the local heating process in this state.

In contrast, in the case of a ferromagnetic layer magnetized in the in-plane direction (X-direction), the magnetization direction of the ferromagnetic layer tends to vary within the plane if the application of a magnetic field is stopped after magnetization in the in-plane direction. This is because, in general, magnetization in the in-plane direction of an in-plane magnetized film, which is magnetized in the in-plane direction, may be relatively unstable and may tend to fluctuate compared to the film-thickness-direction magnetization of a perpendicularly magnetized film, which is magnetized in the film thickness direction. If a local heating process is performed in this state, a state in which the magnetization direction varies becomes pinned. To avoid this, the application of a magnetic field to the ferromagnetic layer may be continued and the local heating process performed while maintaining the magnetization state in which the ferromagnetic layer is magnetized in the X-direction. In other words, the method of this example embodiment, in which the magnetizing process and the local heating process are performed separately, is not very suitable for a magnetic sensor in which first magnetically pinned layer 63 is magnetized in the in-plane direction but is suitable for a magnetic sensor 1 in which first magnetically pinned layer 63 is magnetized in the film thickness direction.

### Second Example Embodiment

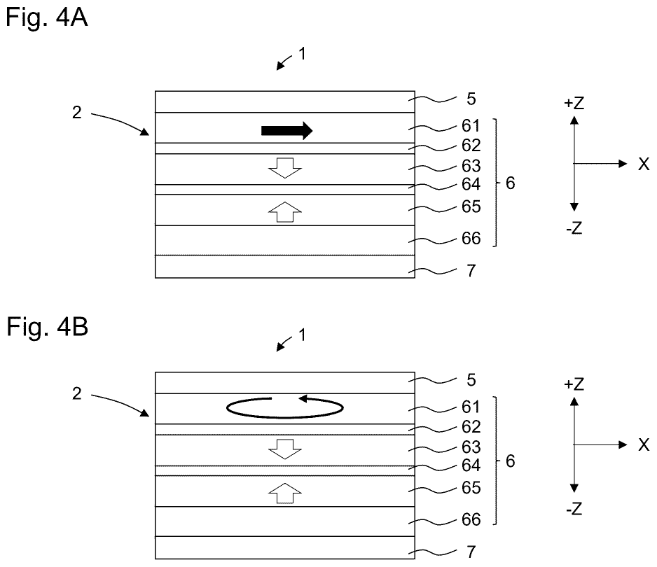

FIG. 4A shows the schematic structure of magnetic sensor 1 according to the second example embodiment. Explanation of structure and effects that are the same as in the first example embodiment are omitted from the description. Magnetic laminated body 6 may comprise magnetically free layer 61, nonmagnetic layer 62, first magnetically pinned layer 63, intermediate layer 64, second magnetically pinned layer 65, and antiferromagnetic layer 66. Magnetically free layer 61, nonmagnetic layer 62, first magnetically pinned layer 63, and antiferromagnetic layer 66 may be configured as in the first example embodiment. Antiferromagnetic layer 66 may have the same effect as the first example embodiment. These layers may also be arranged in the order of magnetically free layer 61, nonmagnetic layer 62, first magnetically pinned layer 63, intermediate layer 64, second magnetically pinned layer 65, and antiferromagnetic layer 66, in the −Z-direction from upper electrode layer 5 to lower electrode layer 7, and layers adjacent to each other may be in contact with each other. In other words, in this example embodiment, second magnetically pinned layer 65 may be a magnetically pinned layer in contact with antiferromagnetic layer 66, and first magnetically pinned layer 63 may be an intermediate ferromagnetic layer. These layers may also be stacked in the opposite direction. Specifically, they may be arranged in the order of antiferromagnetic layer 66, second magnetically pinned layer 65, intermediate layer 64, first magnetically pinned layer 63, nonmagnetic layer 62, and magnetically free layer 61 in the −Z-direction from upper electrode layer 5 to lower electrode layer 7

First magnetically pinned layer 63 may be magnetically coupled with second magnetically pinned layer 65 by synthetic antiferromagnetic coupling through intermediate layer 64. The magnetization direction of first magnetically pinned layer 63 is pinned in the direction opposite to the magnetization direction of second magnetically pinned layer 65. First magnetically pinned layer 63 and second magnetically pinned layer 65 can be formed of multilayer films of Co and Pt films, or of materials with large perpendicular magnetic anisotropy, such as multilayer films of Co and Pd films, Co and Ni films, or the like. Intermediate layer 64 may be formed of a nonmagnetic metal that generates RKKY (Ruderman-Kittel-Kasuya-Yosida) coupling, such as ruthenium or the like. The multilayer film comprising first magnetically pinned layer 63, intermediate layer 64, and second magnetically pinned layer 65 may also be called a SAF (Synthetic Antiferromagnetic) structure. Because the magnetization directions of first magnetically pinned layer 63 and second magnetically pinned layer 65 may be oriented in opposite directions, the leakage magnetic field applied from first magnetically pinned layer 63 to magnetically free layer 61 may be suppressed. The magnitude of the magnetic moment of first magnetically pinned layer 63 and that of second magnetically pinned layer 65 can be made almost the same. In FIGS. 4A and 4B, first magnetically pinned layer 63 may be magnetized in the −Z-direction and second magnetically pinned layer 65 may be magnetized in the +Z-direction, but first magnetically pinned layer 63 may also be magnetized in the +Z-direction and second magnetically pinned layer 65 may be magnetized in the −Z-direction.

FIG. 4B shows the schematic structure of a variation of magnetic sensor 1 according to the second example embodiment. The magnetization direction of magnetically free layer 61 may have a vortex shape in the plane perpendicular to the Z-direction in the zero magnetic field state. For details, see the description of the first example embodiment.

### Method for Manufacturing Magnetic Sensor 1

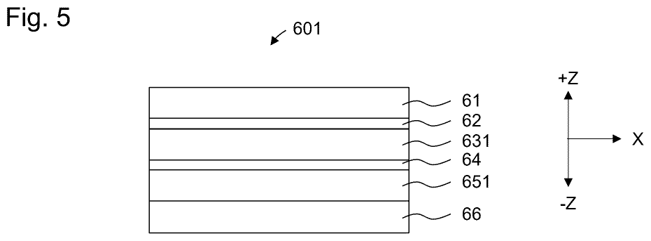

Magnetic sensor 1 of this example embodiment may be manufactured by the same method as in the first example embodiment. To manufacture magnetic sensor 1, lower electrode layer 7, laminated film 601, and upper electrode layer 5 may be first sequentially formed on wafer 8 that is a substrate (Step S1). FIG. 5 shows the structure of laminated film 601 in this example embodiment. Laminated film 601 in this example embodiment may be formed by sequentially forming antiferromagnetic layer 66, ferromagnetic layer 651, intermediate layer 64, ferromagnetic layer 631, nonmagnetic layer 62, and magnetically free layer 61 in the +Z-direction on lower electrode layer 7. Next, the magnetization process (Step S2) may be performed as in the first example embodiment. Ferromagnetic layer 651, which is in contact with the antiferromagnetic layer 66, may be magnetized to become second magnetically pinned layer 65, and ferromagnetic layer 631 may be magnetized to become first magnetically pinned layer 63. Next, a local heating process (Step S3) may be performed to firmly pin the magnetization direction of second magnetically pinned layer 65 in the Z-direction. The devices used in the magnetization process and the local heating process are the same as in the first example embodiment. For details, see the description of the first example embodiment.

In this example embodiment, when a magnetic field is applied in the magnetization process (Step S2) (e.g., in the +Z-direction), ferromagnetic layer 651 and ferromagnetic layer 631 may be magnetized in the same direction (the +Z-direction). When the application of a magnetic field is stopped, the magnetization directions of ferromagnetic layer 651 and ferromagnetic layer 631 may be oriented in opposite directions to each other due to the SAF structure. In other words, either the magnetization direction of ferromagnetic layer 651 or that of ferromagnetic layer 631 may be reversed (the magnetization direction may be oriented in the −Z-direction). Next, the local heating process (Step S3) may be performed to pin the magnetization directions of ferromagnetic layer 651 and ferromagnetic layer 631. Therefore, either the magnetization direction of first magnetically pinned layer 63 or the magnetization direction of second magnetically pinned layer 65 may be opposite to the direction in which the magnetic field is applied during magnetization. There is no functional problem even if the magnetization direction of either ferromagnetic layer is reversed. However, since magnetic sensor 1 may usually be manufactured in large quantities in wafer or lot units, variation in the magnetization direction of first magnetically pinned layer 63 and that of second magnetically pinned layer 65 on the same wafer or in the same lot will result in variation in output on the same wafer or in the same lot and is therefore undesirable.

Which of ferromagnetic layer 651 or ferromagnetic layer 631 that undergoes a reversal of magnetization direction when the application of a magnetic field is stopped depends on the magnetic properties of ferromagnetic layer 651 and ferromagnetic layer 631. For example, the magnetization direction of a ferromagnetic layer having a small magnetic moment is more likely to reverse than that of a ferromagnetic layer having a large magnetic moment. Therefore, to suppress variation of the magnetization direction, the magnetic moments of ferromagnetic layer 651 and ferromagnetic layer 631 may be caused to differ from each other to some extent. For example, if ferromagnetic layer 651 and ferromagnetic layer 631 are formed from the same material, the film thickness or volume can be caused to differ. The ferromagnetic layer having a larger film thickness or larger volume will also have a larger magnetic moment. If the film thicknesses or volumes of ferromagnetic layer 651 and ferromagnetic layer 631 are almost the same, materials having different magnetic moments per volume can be used. However, if the difference in magnetic moment between ferromagnetic layer 651 and ferromagnetic layer 631 is too large, the leakage magnetic field from ferromagnetic layer 631 will have a greater effect on magnetically free layer 61. Therefore, when the magnetic moment of first magnetically pinned layer 63 is M1 and the magnetic moment of second magnetically pinned layer 65 is M2,

$$\vert M 2 - M 1 \vert / M 1$$

may be between 3% and 20%.

Since a ferromagnetic layer having small perpendicular magnetic anisotropy tends to undergo a reversal of magnetization direction more easily than a ferromagnetic layer having large perpendicular magnetic anisotropy, a difference in the magnitude of perpendicular magnetic anisotropy between first magnetically pinned layer 63 and second magnetically pinned layer 65 can be provided. For example, if first magnetically pinned layer 63 and second magnetically pinned layer 65 are formed by multilayer films (e.g., Co and Pt films), a difference in the magnitude of perpendicular magnetic anisotropy can be provided by changing the thickness ratio of the films that make up the multilayer film (e.g., Co and Pt films). This method may be for suppressing the influence of leakage magnetic fields because the magnetic moments of first magnetically pinned layer 63 and second magnetically pinned layer 65 may be the same.

### Third Example Embodiment

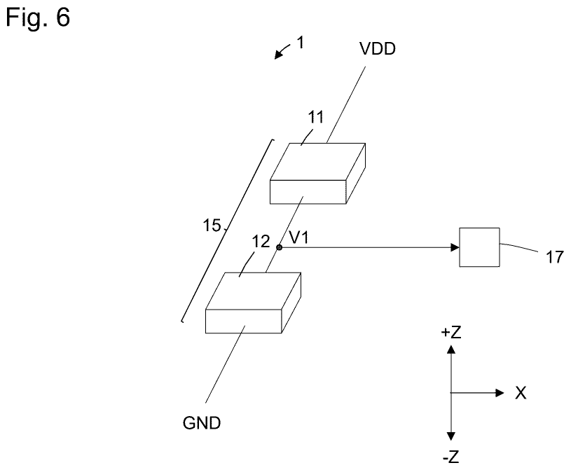

FIG. 6 shows the schematic structure of magnetic sensor 1 according to a third example embodiment. Magnetic sensor 1 of this example embodiment may comprise abovementioned magnetic field sensing elements 2 of the first and second example embodiments combined as a half bridge. Magnetic sensor 1 may comprise first and second element units 11 and 12 each comprising at least one magnetic field sensing element 2. In one example, each of first and second element units 11 and 12 may comprise an array of a plurality of magnetic field sensing elements 2 that are connected in series. First and second element units 11 and 12 may be connected in series to form group 15. One end of group 15 may be connected to power supply VDD and the other end may be grounded (GND). Voltage drops in first and second element units 11 and 12 may be approximately proportional to the electrical resistances of first and second element units 11 and 12. Therefore, if the electrical resistances of first and second element units 11 and 12 are R1 and R2, respectively, midpoint voltage V1 may satisfy V1=R2/(R1+R2)×VDD. Magnetic sensor 1 may comprise output section 17 located between first and second element units 11 and 12, and output section 17 may output midpoint voltage V1.

The magnetization direction of the magnetically pinned layer in contact with antiferromagnetic layer 66 of first element unit 11 and the magnetization direction of the magnetically pinned layer in contact with antiferromagnetic layer 66 of second element unit 12 are opposite to each other. The magnetically pinned layer in contact with antiferromagnetic layer 66 is first magnetically pinned layer 63 in the first example embodiment and second magnetically pinned layer 65 in the second example embodiment.

### Method for Manufacturing Magnetic Sensor 1

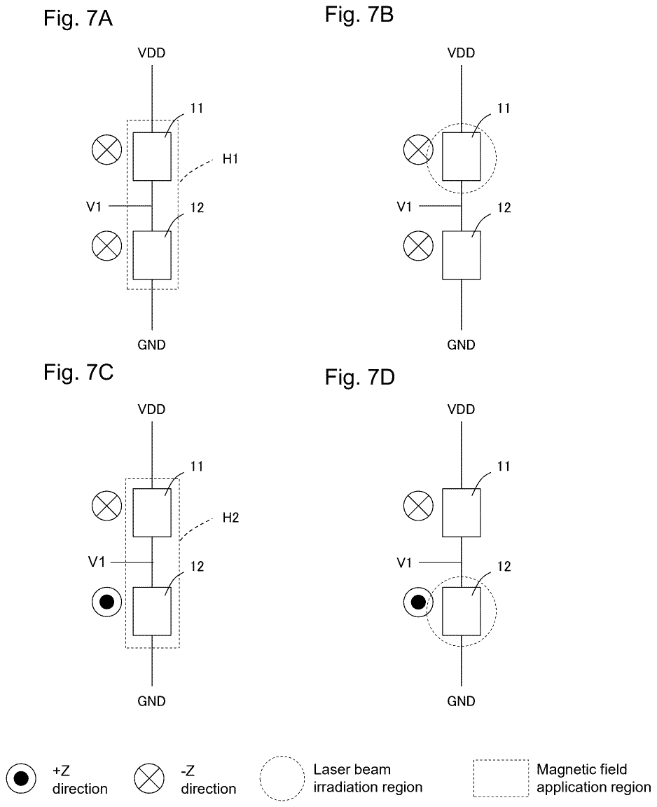

Magnetic sensor 1 according to a third example embodiment may be a combination of multiple magnetic field sensing elements 2, and individual magnetic field sensing elements 2 may be made by the abovementioned manufacturing methods of each example embodiment. Explanation will here focus on the magnetization process and local heating process of each of element units 11 and 12 with reference to FIGS. 7A to 7D. Magnetic field sensing element 2 may comprise magnetic laminated body 6 of the first example embodiment, but magnetic field sensing element 2 comprising magnetic laminated body 6 of the second example embodiment may also be manufactured in the same way. The symbols indicating the +Z-direction and the −Z-direction in FIGS. 7A-7D may indicate the magnetization direction of ferromagnetic layer 631 or first magnetically pinned layer 63 in FIGS. 2A and 2B.

First, as shown in FIG. 7A, first magnetic field H1 in the −Z-direction may be applied to first and second element units 11 and 12, following which the application of first magnetic field H1 is stopped. Ferromagnetic layer 631 of first element unit 11 may be magnetized in the −Z-direction to become first magnetically pinned layer 63. At this time, ferromagnetic layer 631 of second element unit 12 may also be magnetized in the −Z-direction. Next, as shown in FIG. 7B, first element unit 11 may be irradiated with a laser beam to heat first element unit 11 to a temperature equal to or higher than the blocking temperature of antiferromagnetic layer 66 of first element unit 11 to pin the magnetization direction of first magnetically pinned layer 63 by exchange coupling with antiferromagnetic layer 66. Heating of second element unit 12 may be kept at a sufficiently low level to perform the local heating by the laser beam.

Next, as shown in FIG. 7C, second magnetic field H2 in the +Z-direction may be applied to first and second element units 11 and 12, following which the application of second magnetic field H2 is stopped. Second magnetic field H2 may be in the direction opposite to first magnetic field H1 (the directions are different from each other by 180°). Second magnetic field H2 should have at least a component in the direction opposite to first magnetic field H1. Ferromagnetic layer 631 of second element unit 12 is already magnetized in the −Z-direction, but when a magnetic field in the +Z-direction is applied, ferromagnetic layer 631 is magnetized in the +Z-direction to become first magnetically pinned layer 63. At this time, the magnetization direction of first magnetically pinned layer 63 of first element unit 11 may temporarily reverse, but when the application of the magnetic field is halted, the magnetization direction returns to the −Z-direction by exchange coupling with antiferromagnetic layer 66. Next, as shown in FIG. 7D, second element unit 12 may be irradiated with a laser beam and second element unit 12 may be heated to a temperature equal to or higher than the blocking temperature of antiferromagnetic layer 66 of second element unit 12 to pin the magnetization direction of first magnetically pinned layer 63 by exchange coupling with antiferromagnetic layer 66. Laser beams are irradiated at multiple positions. Considering the formation accuracy of the element unit and other factors, the intervals between the laser beam irradiation positions may be about 5 μm or more and may be 10 μm or more.

In this example embodiment, first or second element units 11 and 12 may be locally heated using laser annealing, but the heating method is not limited to laser light as long as first element unit 11 or second element unit 12 can be locally heated. For example, wiring for heating may be provided near first element unit 11 and second element unit 12, and first element unit 11 and second element unit 12 may be selectively heated by energizing the wiring for heating and generating heat in the wiring for heating.

### Fourth Example Embodiment

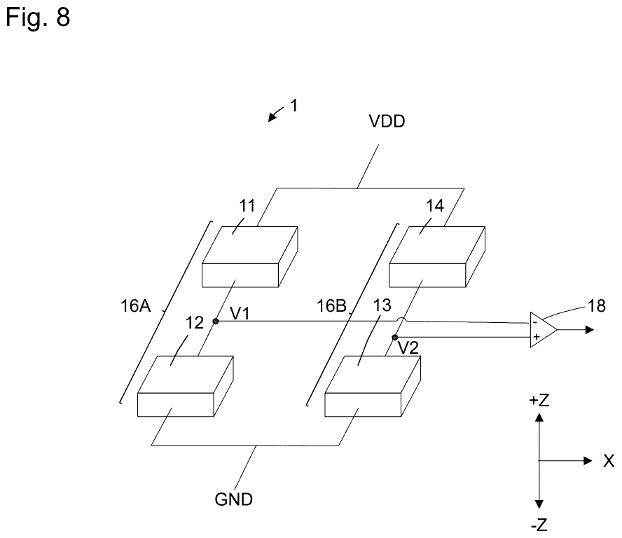

FIG. 8 shows the schematic structure of magnetic sensor 1 according to the fourth example embodiment. Magnetic sensor 1 of this example embodiment may comprise abovementioned magnetic field sensing elements 2 of the first and second example embodiments combined as a full bridge. Magnetic sensor 1 may comprise first to fourth element units 11-14 each comprising at least one magnetic field sensing element 2. In one example, each of first to fourth element units 11-14 may comprise an array of a plurality of magnetic field sensing elements 2 that are connected in series. First and second element units 11 and 12 may be connected in series to form first group 16A. Third and fourth element units 13 and 14 may be connected in series to form second group 16B. One end of each of first and second groups 16A and 16B may be connected to power supply VDD and the other ends of each of first and second groups 16A and 16B may be grounded (GND). First element unit 11 and fourth element unit 14 may be located on the power-supply-VDD side, and second element unit 12 and third element unit 13 may be located on the ground side (GND). Magnetic sensor 1 may comprise differentiator 18 for determining the difference between output V1, which is between first element unit 11 and second element unit 12, and output V2, which is between third element unit 13 and fourth element unit 14.

The magnetization directions of the magnetically pinned layers that are in contact with antiferromagnetic layer 66 of first and third element units 11 and 13 are the same direction. The magnetization directions of the magnetically pinned layers that are in contact with antiferromagnetic layers 66 of second and fourth element units 12 and 14 are opposite to the magnetization direction of the magnetically pinned layers that are in contact with antiferromagnetic layer 66 of first and third element units 11 and 13. The magnetically pinned layers that are in contact with antiferromagnetic layers 66 may be first magnetically pinned layers 63 in the first example embodiment and may be second magnetically pinned layers 65 in the second example embodiment.

Voltage drops in each of element units 11-14 may be approximately proportional to the electrical resistances of first to fourth element units 11-14. Therefore, if the electrical resistances of first to fourth element units 11-14 are R1-R4, respectively, midpoint voltage V1 may satisfy V1=R2/(R1+R2)×VDD, and midpoint voltage V2 may satisfy V2=R3/(R3+R4)×VDD. By determining difference V1−V2 between midpoint voltages V1 and V2 by differentiator 18, the sensitivity is twice as high as when detecting midpoint voltages V1 and V2. Even if midpoint voltages V1 and V2 are offset, the effect of the offset can be eliminated by detecting the difference.

### Method for Manufacturing Magnetic Sensor 1

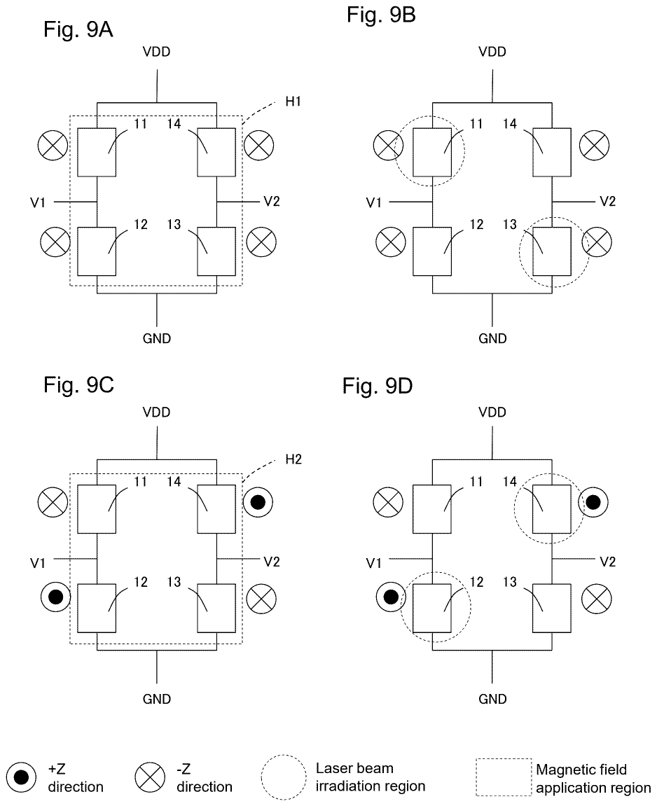

Magnetic sensor 1 according to the fourth example embodiment may be a combination of multiple magnetic field sensing elements 2, and individual magnetic field sensing elements 2 may be made by the abovementioned manufacturing method of each example embodiment. The following explanation will focus on the magnetization process and local heating process of each of element units 11-14 with reference to FIGS. 9A to 9D. These processes may be basically the same as those in the third example embodiment. Magnetic field sensing elements 2 may comprise magnetic laminated bodies 6 of the first example embodiment, but magnetic field sensing elements 2 comprising magnetic laminated bodies 6 of the second example embodiment may also be manufactured in the same way. The symbols indicating the +Z-direction and the −Z-direction in FIGS. 9A-9D may indicate the magnetization directions of ferromagnetic layers 631 or first magnetically pinned layers 63 in FIGS. 2A and 2B.

First, as shown in FIG. 9A, first magnetic field H1 in the −Z-direction may be applied to first to fourth element units 11-14, following which the application of first magnetic field H1 is stopped. Ferromagnetic layers 631 of first and third element units 11 and 13 may be magnetized to become first magnetically pinned layers 63. Next, as shown in FIG. 9B, first and third element units 11 and 13 may be irradiated with a laser beam to heat first and third element units 11 and 13 to a temperature equal to or higher than the blocking temperature of antiferromagnetic layers 66 of first and third element units 11 and 13 to pin the magnetization directions of first magnetically pinned layers 63 by exchange coupling with antiferromagnetic layers 66. Next, as shown in FIG. 9C, second magnetic field H2 in the +Z-direction may be applied to first to fourth element units 11-14, following which the application of second magnetic field H2 is stopped. Ferromagnetic layers 631 of second and fourth element units 12 and 14 may be magnetized in the +Z-direction to become first magnetically pinned layers 63. Next, as shown in FIG. 9D, second and fourth element units 12 and 14 may be irradiated with a laser beam to heat second and fourth element units 12 and 14 to a temperature equal to or higher than the blocking temperature of antiferromagnetic layers 66 of second and fourth element units 12 and 14 to pin the magnetization direction of first magnetically pinned layers 63 by exchange coupling with antiferromagnetic layers 66. In this example embodiment, the intervals between the laser beam irradiation positions may be about 5 μm or more, and may be about 10 μm or more.

### Example

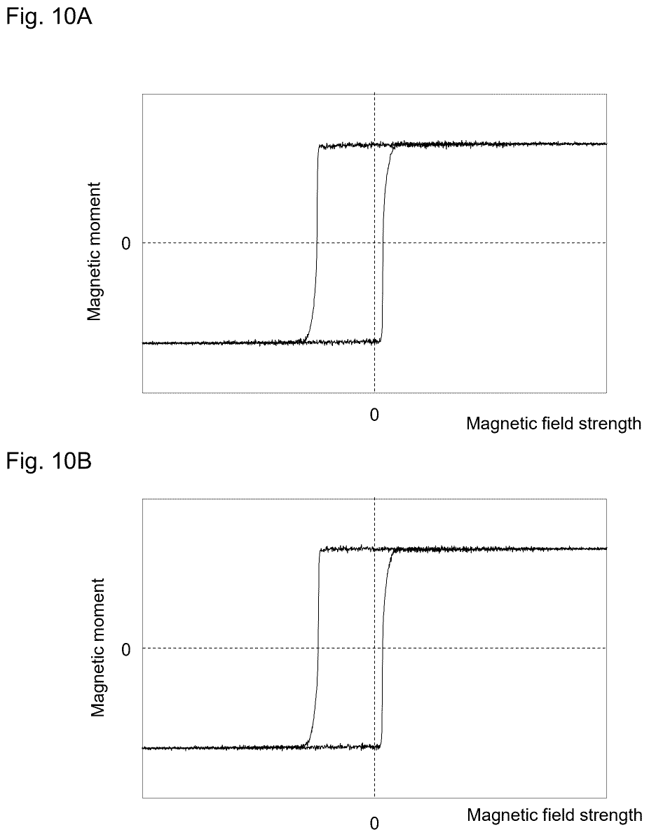

Samples that comprise stacked antiferromagnetic layers and ferromagnetic layers were prepared and magnetization curves were obtained. In this example, a magnetic field in the direction perpendicular to the film surface of a ferromagnetic layer was applied to the prepared samples, and the samples were heated after the application of the magnetic field was stopped. In Comparative Example 2, a magnetic field in the direction perpendicular to the film surface of a ferromagnetic layer was applied to the prepared samples while simultaneously heating the samples. The present example corresponds to the first to fourth example embodiments, and Comparative Example 2 corresponds to Comparative Example 1. FIG. 10A shows the magnetization curve of the example and FIG. 10B shows the magnetization curve of Comparative Example 2. The horizontal axis of the magnetization curves indicates the external magnetic field strength, and the vertical axis indicates the magnetic moment. The ranges of the horizontal and vertical axes are the same in FIGS. 10A and 10B. The magnetization curves have almost the same shape in the present example and Comparative Example 2, and the centers of the magnetization curves are at almost the same position on the horizontal axis. This correspondence indicates that there is almost no difference in exchange coupling strength between annealing while applying a magnetic field as in the conventional technology and annealing after applying a magnetic field as in the present example. In other words, the exchange coupling strength in the present example was found to be sufficiently large to pin the magnetization direction of magnetically pinned layers that are in contact with antiferromagnetic layers.

According to the present disclosure, a method can be provided for manufacturing a magnetic laminated body that can simplify a device for magnetizing a magnetically pinned layer and heating an antiferromagnetic layer.

Although preferred example embodiments of the present disclosure have been shown and described in detail, it is to be understood that various changes and modifications are possible without departing from the intent or scope of the appended claims.

### REFERENCE NUMERALS

1 magnetic sensor
2 magnetic field sensing element
6 magnetic laminated body
7 lower electrode layer
11-14 first to fourth element units
61 magnetically free layer
62 first nonmagnetic layer
63 first magnetically pinned layer
64 intermediate layer
65 second magnetically pinned layer
66 antiferromagnetic layer
100 magnetizing and heating device
101 magnetic field application device
102 heating device
103 transfer device

1. A method for manufacturing a magnetic laminated body comprising steps of:
forming a laminated film comprising a ferromagnetic layer and an antiferromagnetic layer in which the ferromagnetic layer and the antiferromagnetic layer are in contact with each other in a first direction;
forming, from the ferromagnetic layer, a magnetically pinned layer that has a pinned magnetization direction with respect to an external magnetic field by applying a magnetic field in the first direction to the laminated film; and
after stopping application of the magnetic field, heating the laminated film to a temperature equal to or higher than a blocking temperature of the antiferromagnetic layer to form the magnetic laminated body.

2. The method for manufacturing a magnetic laminated body according to claim 1, wherein the laminated film is heated by a laser beam.

3. The method for manufacturing a magnetic laminated body according to claim 1, wherein, after stopping application of the magnetic field, the laminated film is transferred for heating of the laminated film.

4. The method for manufacturing a magnetic laminated body according to claim 1, wherein
the laminated film comprises a magnetically free layer whose magnetization direction changes with respect to an external magnetic field, and a nonmagnetic layer, and
the ferromagnetic layer, the antiferromagnetic layer, the magnetically free layer, and the nonmagnetic layer are arranged in the order of the magnetically free layer, the nonmagnetic layer, the ferromagnetic layer, and the antiferromagnetic layer in the first direction.

5. The method for manufacturing a magnetic laminated body according to claim 1, wherein
the laminated film comprises a magnetically free layer whose magnetization direction changes with respect to an external magnetic field, a nonmagnetic layer, an intermediate ferromagnetic layer, and an intermediate layer that is formed from a nonmagnetic metal, and
the ferromagnetic layer, the antiferromagnetic layer, the magnetically free layer, the nonmagnetic layer, the intermediate ferromagnetic layer, and the intermediate layer are arranged in the order of the magnetically free layer, the nonmagnetic layer, the intermediate ferromagnetic layer, the intermediate layer, the ferromagnetic layer, and the antiferromagnetic layer in the first direction.

6. The method for manufacturing a magnetic laminated body according to claim 5, wherein, when magnetic moment of the intermediate ferromagnetic layer is M1 and magnetic moment of the ferromagnetic layer is M2, |M2−M1|/M1 is between 3% and 20%.

7. The method for manufacturing a magnetic laminated body according to claim 5, wherein magnitudes of perpendicular magnetic anisotropy of the intermediate ferromagnetic layer and the ferromagnetic layer are different from each other.

8. The method for manufacturing a magnetic laminated body according to claim 5, wherein the magnetization direction of the magnetically free layer has a vortex shape in a plane perpendicular to the first direction in a state in which the external magnetic field is not applied.

9. The method for manufacturing a magnetic laminated body according to claim 5, wherein the nonmagnetic layer comprises an insulating layer.

10. A method for manufacturing a magnetic sensor comprising steps of:
arranging a ferromagnetic layer, a magnetically free layer whose magnetization direction changes with respect to an external magnetic field, a nonmagnetic layer, and an antiferromagnetic layer in the order of the magnetically free layer, the nonmagnetic layer, the ferromagnetic layer, and the antiferromagnetic layer in a first direction;
forming a group of a first element unit and a second element unit in which said first element unit and said second element unit are connected in series, wherein each of said first and second element units comprises laminated film in which said ferromagnetic layer and said antiferromagnetic layer are in contact with each other, and in which one end of the group is connected to a power supply and other end is grounded;
providing an output section between the first element unit and the second element unit;
forming, from the ferromagnetic layer of the first element unit, a magnetically pinned layer, which has a pinned magnetization direction with respect to an external magnetic field, by applying a first magnetic field in the first direction to the first element unit;
after stopping application of the first magnetic field, heating the first element unit to a temperature equal to or higher than a blocking temperature of the antiferromagnetic layer of the first element unit;
forming, from the ferromagnetic layer of the second element unit, a magnetically pinned layer, which has a pinned magnetization direction with respect to an external magnetic field, by applying a second magnetic field including a component in a direction opposite to the first direction to the second element unit; and
after stopping application of the second magnetic field, heating the second element unit to a temperature equal to or higher than a blocking temperature of the antiferromagnetic layer of the second element unit.

11. A method for manufacturing a magnetic sensor comprising steps of:
arranging a ferromagnetic layer, a magnetically free layer whose magnetization direction changes with respect to an external magnetic field, a nonmagnetic layer, and an antiferromagnetic layer in the order of the magnetically free layer, the nonmagnetic layer, the ferromagnetic layer, and the antiferromagnetic layer in a first direction;
forming a first group of a first element unit and a second element unit in which said first element unit and said second element unit are connected in series, and forming a second group of a third element unit and a fourth element unit in which said third element unit and said fourth element unit are connected in series, wherein each of the first to fourth element units comprises laminated film in which the ferromagnetic layer and the antiferromagnetic layer are in contact with each other and one end of each of the first and second groups is connected to a power supply and the other ends are grounded, and wherein the first element unit and the fourth element unit are arranged on the power-supply side, and the second element unit and the third element unit are arranged on the ground side;
providing a differentiator for determining a difference between an output that is between the first element unit and the second element unit and an output that is between the third element unit and the fourth element unit;
forming, from the ferromagnetic layers of the first and third element units, magnetically pinned layers, each of which having a pinned magnetization direction with respect to an external magnetic field, by applying a first magnetic field in the first direction to the first and third element units;
after stopping application of the first magnetic field, heating the first and third element units to a temperature equal to or higher than blocking temperatures of the antiferromagnetic layers of the first and third element units;
forming, from the ferromagnetic layers of the second and fourth element units, magnetically pinned layers, each of which having a pinned magnetization direction with respect to an external magnetic field, by applying a second magnetic field including a component in a direction opposite to the first direction to the second and fourth element units; and
after stopping application of the second magnetic field, heating the second and fourth element units to a temperature equal to or higher than blocking temperatures of the antiferromagnetic layers of the second and fourth element units.

12. The method for manufacturing a magnetic sensor according to claim 10, wherein the second magnetic field is in a direction opposite to the first direction.

13. An apparatus for manufacturing a magnetic laminated body comprising:
a magnetic field application device that applies a magnetic field in a first direction to a laminated film of a wafer that comprises the laminated film, in which a ferromagnetic layer and an antiferromagnetic layer are in contact with each other in the first direction, to form a magnetically pinned layer from the ferromagnetic layer, wherein a magnetization direction of the magnetically pinned layer is pinned with respect to an external magnetic field;
a heating device that heats the laminated film to a temperature equal to or higher than a blocking temperature of the antiferromagnetic layer; and
a transfer device that transfers the wafer between the magnetic field application device and the heating device.

14. The apparatus for manufacturing a magnetic laminated body according to claim 13, wherein the heating device comprises a laser beam irradiation device for heating the laminated film with a laser beam.
